(19) United States
(12) Patent Application Publication
(10) Pub. No.: US 2022/0178021 A1
(43) Pub. Date: Jun. 9, 2022

(54) WAFER FIXING MECHANISM AND WAFER PRE-CLEANING MACHINE USING THE WAFER FIXING MECHANISM

(71) Applicant: Skytech Co., Ltd., Hsinchu County (TW)

(72) Inventors: CHING-LIANG YI, Hsinchu County (TW); JING-CHENG LIN, Hsinchu County (TW); YAO-Syuan CHENG, Hsinchu County (TW)

(21) Appl. No.: 17/114,503

(22) Filed: Dec. 8, 2020

(51) Int. Cl. C23C 16/458; H01L 21/687; C23C 16/44

(52) U.S. Cl. CPC C23C 16/4585; H01L 21/67098; C23C 16/4412; H01L 21/68785

(57) ABSTRACT

The present disclosure is a thin-film deposition equipment including a chamber, a stage, at least one baffle and at least one shielding component. The stage is for carrying a substrate, the baffle prevents the substrate on the stage from backside coating. The shielding component is positioned higher the baffle for shielding the baffle, to receive target atoms which is yet deposited on the substrate for the baffle. Such that to avoid the target atoms deposited on the baffle forming a thin film, and to further prevent a problem of the thin film from being heated then flowing from the baffle to a contact area between the baffle and the substrate.

### TECHNICAL FIELD

The present disclosure relates to a thin-film deposition equipment, more particularly, to a thin-film deposition equipment which can avoid target atoms forming a thin film on a baffle by at least one shielding component, to prevent the thin film from being heated and flowing to a contact area between the baffle and a substrate then becomes slag.

### BACKGROUND

In manufacturing of integrated circuits, a process of thin-film deposition with high temperature, such as chemical vapor deposition (CVD) or physical vapor deposition (PVD) is commonly required. The process of thin-film deposition is to process a substrate with high-temperature heat treatment, and to cause target atoms form a thin film on a surface of the substrate.

However, during the process of forming a thin film on surface of the substrate, material of the thin film might have defects on the substrate such as protrusions or tiny hillocks, due to heat accumulation or thermal stress. Particularly, when the thin film is formed with a great thickness, there will be more heat accumulation, therefore even easier to have defects on the substrate, and further affects the yield and reliability of products.

To overcome the abovementioned problem, one method is to apply an electrostatic chuck (ESC) instead of the traditional stage. During the deposition process, the electrostatic chuck is used to attract then hold the substrate via electrostatic force, and a coolant gas is blew to the substrate on the electrostatic chuck, thereby to decrease the temperature of the substrate and its heat accumulation, and also to ease the effect of thermal stress. However, the electrostatic chuck is rather expensive and vulnerable, hence it may greatly increase a cost of the deposition process, in comparison with the traditional stage.

Another method is to apply a baffle to lock the substrate on the stage and to transfer the coolant gas between the stage and the substrate during the deposition process, for decreasing temperature of the substrate. However, the target atoms might also be deposited to form a thin film on the baffle, when the heat accumulates more and more, the thin film on the baffle may start to melt then flow to the substrate or a contact area between the baffle and the substrate, cause the substrate and the baffle stick to each other and form with some nasty slag on the substrate, then further reduce the yield and reliability of products.

### SUMMARY

Therefore, an object of the present disclosure to overcome the drawback the prior art, an object of the present disclosure is to provide a thin-film deposition equipment which is disposed with a shielding component above the baffle which locks the substrate. The shielding component can receive a part of target atoms for the baffle, thereby to reduce a probability of the target atoms deposited on the baffle, and further to lessen the nasty slag forming on the substrate and sticking the substrate and the baffle together.

According to the abovementioned object, the present disclosure provides a thin-film deposition device including a chamber, a stage, at least one baffle and at least one shielding component. The chamber has a containing space, the stage is used to carry a substrate. The baffle is positioned in the containing space, for preventing the backside coating of the substrate on the stage. The shielding component is positioned higher than the baffle, and the shielding component has a cavity on an upper surface thereof.

Optionally, the thin-film deposition equipment further includes a pin. The pin is engaged with a first concave portion of an upper surface of the baffle and a second concave portion of a lower surface of the shielding component, such that the shielding component is connected to the baffle via the pin.

Optionally, a distance between the shielding component and the baffle is adjustable, by replacing the pin with another pin of different length.

Optionally, the upper surface of the baffle has a first concave portion, the shielding component has a first protruding portion, and the first concave portion of the baffle is corresponding to and engaged with the first protruding portion of the shielding component, thereby the shielding component and the baffle are connected.

Optionally, the upper surface of the baffle has a second protruding portion, the lower surface of the shielding component has a second concave portion, the second protruding portion of the baffle is corresponding to and engaged with the second concave portion of the shielding component, thereby the shielding component is connected to the baffle.

Optionally, the thin-film deposition equipment further includes at least one cooling-cycle passage that contacts the baffle. The cooling-cycle passage is for transferring a coolant fluid, to decrease temperature of the baffle.

Optionally, the thin-film deposition equipment further includes an upper shielding component that is connected to the chamber and positioned higher than the shielding component.

Optionally, the upper shielding component further has an end disposed with a protruding portion, for forming an upper-shielding component cavity between the protruding portion and the chamber.

Optionally, the upper shielding component is made of stainless steel, titanium or aluminum alloy.

Optionally, the cooling-cycle passage contacts the upper shielding component, and transferring coolant fluid to decrease temperature of the upper shielding component.

Optionally, the shielding component has a connecting portion and a shielding portion, the shielding portion is connected the chamber via the connecting portion. The shielding portion further includes a first protruding portion, to form a cavity between the first protruding portion and the connecting portion.

Optionally, the shielding portion further includes a second protruding portion to form a groove on the shielding portion, and the groove is disposed between the first protruding portion and the second protruding portion.

Optionally, the connecting portion further includes a seat portion and holding portion. The seat portion is connected to the chamber, and the holding portion is connected to the shielding portion. Moreover, the connecting portion further includes a cavity, and the cavity is disposed between the seat portion and the holding portion.

Optionally, the shielding portion further includes a first end, a second end and a catch area. The first end is connected to the connecting portion, the second end is connected to the first end, and the catch area is positioned between the first end and the second end. Furthermore, the second end has a top portion that is positioned higher than the catch area, thereby the cavity is between the second end and the connecting portion.

Optionally, the shielding component is made of stainless steel, titanium or aluminum alloy.

Optionally, the thin-film deposition equipment further includes a coolant-gas inlet that is connected to the stage, for transferring the coolant gas between the stage and the substrate to decrease temperature of the substrate.

Optionally, the thin-film deposition equipment further includes a target shield above the shielding component.

To be brief, the thin-film deposition equipment according to the present disclosure can receive a part of target atoms by the shielding component, for reducing deposition of the target atoms on the baffle, and further reduce defect occurring on the substrate during the deposition, therefore the thin-film deposition equipment has an advantage in the market which demands thin-film deposition.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a schematic diagram of thin-film deposition equipment according to one embodiment of the present disclosure.

FIG. 2 is a schematic diagram of thin-film deposition equipment according to another embodiment of the present disclosure.

FIG. 3 is a schematic diagram of thin-film deposition equipment according to another embodiment of the present disclosure.

FIG. 4 is a schematic diagram of thin-film deposition equipment according to another embodiment of the present disclosure.

FIG. 5 is a schematic diagram of thin-film deposition equipment according to another embodiment of the present disclosure.

FIG. 6 is a schematic diagram of thin-film deposition equipment according to another embodiment of the present disclosure.

FIG. 7 is a schematic diagram of thin-film deposition equipment according to another embodiment of the present disclosure.

FIG. 8 is a schematic diagram of thin-film deposition equipment according to another embodiment of the present disclosure.

FIG. 9 is a schematic diagram of thin-film deposition equipment according to another embodiment of the present disclosure.

FIG. 10 is a schematic diagram of thin-film deposition equipment according to another embodiment of the present disclosure.

FIG. 11 is a schematic diagram of thin-film deposition equipment according to another embodiment of the present disclosure.

FIG. 12 is a schematic diagram of thin-film deposition equipment according to another embodiment of the present disclosure.

FIG. 13 is a schematic diagram of thin-film deposition equipment according to another embodiment of the present disclosure.

FIG. 14 is a schematic diagram of thin-film deposition equipment according to another embodiment of the present disclosure.

FIG. 15 is a schematic diagram of thin-film deposition equipment according to another embodiment of the present disclosure.

### DETAILED DESCRIPTION OF THE PREFERRED EMBODIMENTS

To fully understand purposes, characteristics and functions of the present disclosure, herein to describe details thereof by the following specific embodiment(s) with the attached figures.

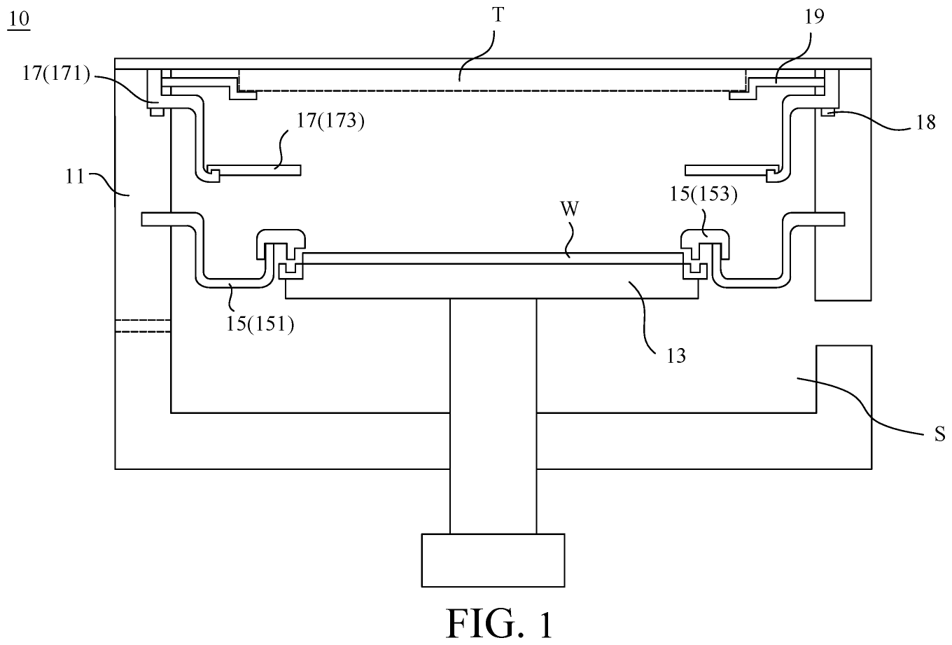

At first referring to FIG. 1, which is a schematic diagram of thin-film deposition equipment 10 according to an embodiment of the present disclosure. As shown in FIG. 1, the thin-film deposition equipment 10 has a chamber 11, a stage 13, at least one baffle 15 and at least one shielding component 17. The chamber 11 has a containing space (S), the stage 13 and the baffle 15 is positioned within the containing space (S) of the chamber 11. The stage 13 is used to carry at least one substrate (W), and the baffle 15 is used to contact the substrate (W) on the stage 13 for locking the substrate (W) on the stage 13. Furthermore, the baffle 15 is also used for preventing backside coating of the substrate (W) on the stage 13.

Specifically, the baffle 15 has a main body 151 and a cap ring 153, the main body 151 has an end connected to an inner wall of the chamber 11, and the cap ring 153 forms a circular space therein. The stage 13 is in a position perpendicularly extending from the circular space formed by the baffle 15. When the stage 13 approaches the baffle 15, the cap ring 153 of the baffle 15 will contact the substrate (W) on the stage 13, to prevent the substrate (W) from falling off the stage 13. In an embodiment, the main body 151 and the cap ring 153 of the baffle 15 may be formed integrally as one component.

During the process of thin-film deposition, the substrate (W) forms a thin film on a surface thereof. Taking an example from sputter deposition of physical vapor deposition (PVD), commonly a target material (T) is disposed inside of the chamber 11, and a target shield 19 is disposed below and outside of the target material (T), wherein the target material (T) and the substrate (W) faces each other. Ingredient of the target material (T) may be aluminum-copper alloy, aluminum-silicon-copper alloy, pure aluminum, copper, titanium, silver, gold, nicker-vanadium alloy, tungsten or titanium-tungsten alloy, but not limited thereto.

In process of thin-film deposition, when a processing gas is transferred into the containing space (S) of the chamber 11 (not shown), a high voltage will be applied on the target material (T) and the substrate (W), thereby to generate a gas with high-voltage electric field in the containing space (S) between the target material (T) and the substrate (W), wherein the processing gas may be such as noble gas but not limited thereto. The high-voltage electric field will deionize the processing gas in the containing space (S) between the target material (T) and the substrate (W), and generate plasma. Positive-charged ions in the plasma will accelerate as attracted by a negative voltage of the target material (T) and hit the surface of the target material (T), thereby target atoms in the target material (T) will gain kinetic energy and leave the surface of the target material (T) then be deposited on the surface of the substrate (W). However, although this embodiment is exemplified by physical vapor deposition, claim scope of the present disclosure is not limited thereto, the thin-film deposition equipment of the present disclosure may also adapt to chemical vapor deposition.

In an embodiment, the thin-film deposition equipment 10 may be disposed with a coolant-gas inlet that is connected to the stage 13 (not shown), and transfers a coolant gas between the stage 13 and the substrate (W) via the coolant-gas inlet, allow the coolant gas to contact the substrate (W) on the stage 13, to decrease temperature of the substrate (W), then the baffle 15 can block the substrate (W) on the stage 13 and prevent the substrate (W) from falling or moving by the blowing coolant gas.

The shielding component 17 of the thin-film deposition equipment 10 is positioned higher than the baffle 15 and covers the baffles 15, to receive a part of target atoms that are yet deposited on the substrate (W) for the baffle 15. Such that the shielding component 17 reduces the deposition of target atoms on the baffle 15 and lessen the thin film forming thereon, hence the minimized thin film on the baffle 15 will not flow from the baffle 15 into an contact area of the baffle 15 and the substrate (W) when being heated, and thereby to improve the drawback of slag forming between the baffle 15 and the substrate (W). The shielding component 17 is made of such as stainless steel, titanium or aluminum alloy, but not limited thereto.

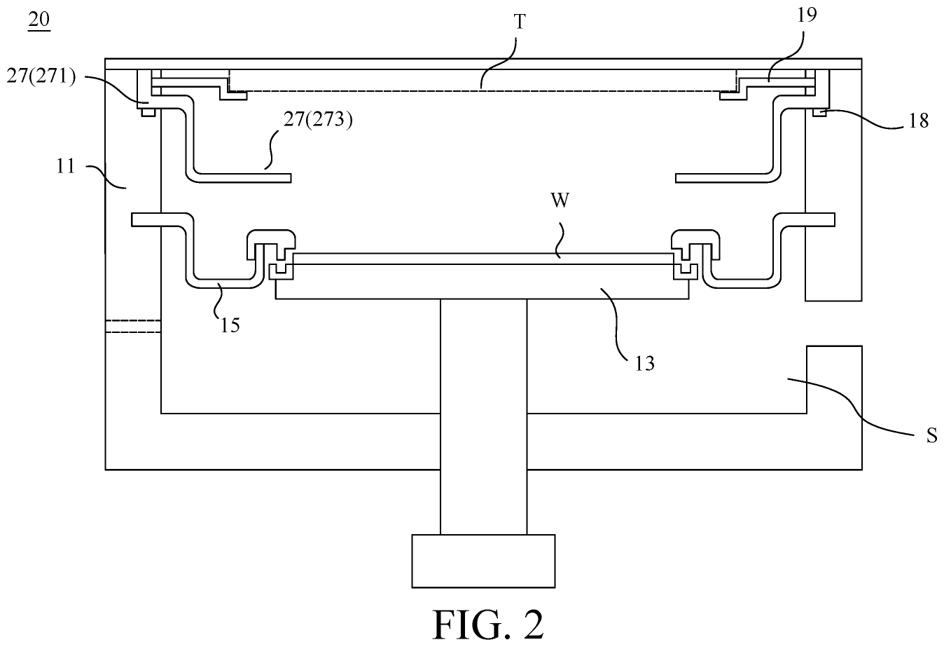

Specifically, the shielding component 17 has a connecting portion 171 and a shielding portion 173, wherein the shielding portion 171 is connected to the chamber 11 via the connecting portion 171. As shown in FIG. 1, the connecting portion 171 and the shielding portion 173 may be two components which can be assembled to the shielding component 17, or as shown in FIG. 2, the connecting portion 271 and the shielding portion 273 of the thin-film deposition equipment 20 may be formed integrally as one shielding component 27. Also, the shielding component 17, 27 is not limited to align with the baffle 15, the shielding component 17, 27 may be positioned ahead of, behind of or aligned with the baffle 15.

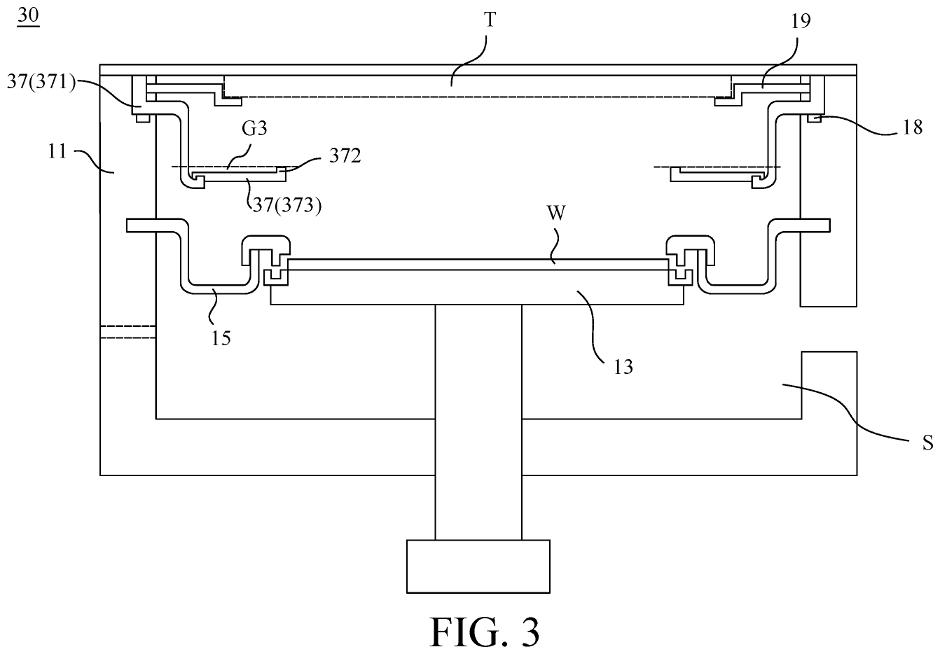

Referring to FIG. 3, which is a schematic diagram of thin-film deposition equipment 30 according to another embodiment of the present disclosure. The thin-film deposition equipment 30 is mostly the same as the previous embodiment. In one embodiment, the shielding portion 373 of the shielding component 37 of the thin-film deposition equipment 30 further includes a first protruding portion 372 to form a cavity (G3) between the first protruding portion 372 and the connecting portion 371. The cavity (G3) is used to receive a part of the target atoms and to prevent the target atoms deposited on the shielding component 37 from being heated and melting and then dripping onto the substrate (W). The first protruding portion 372 may be positioned at an end of the shielding portion 373, however the present disclosure is not limited thereto, the first protruding portion 372 can be positioned anywhere on the shielding portion 373.

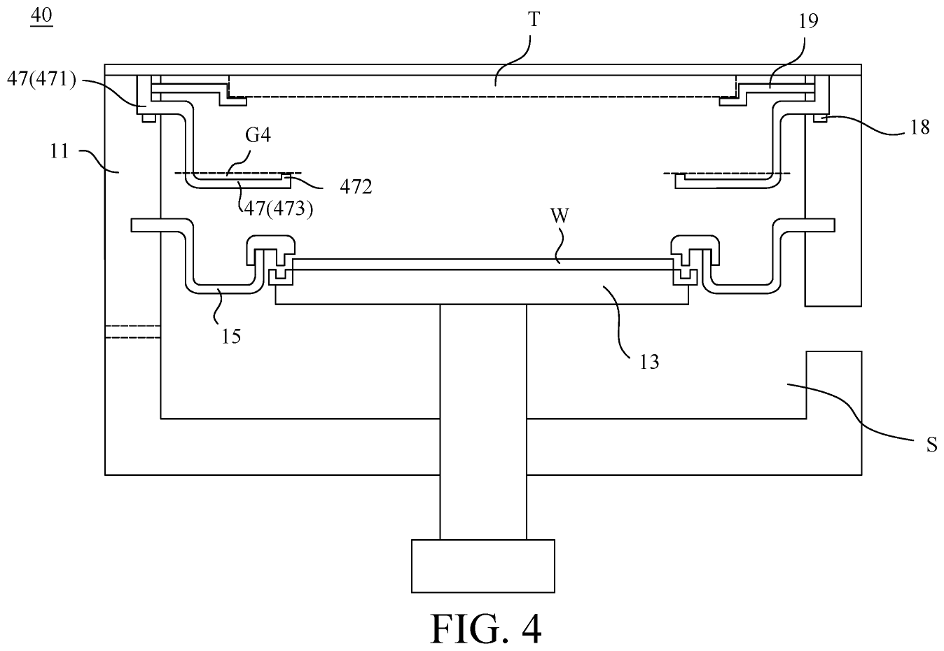

Likewise, the connecting portion 371 and the shielding portion 373 may be two components that are assembled to the shielding component 37. Otherwise as shown in FIG. 4, the connecting portion 471 and the shielding portion 473 of the thin-film deposition equipment 40 may also be formed integrally as one shielding component 47, and has the cavity (G4) formed between the first protruding portion 472 and the connecting portion 471, to receive a part of the target atoms and to prevent the target atoms deposited on the shielding component 47 from being heated and melting and then dripping onto the substrate (W).

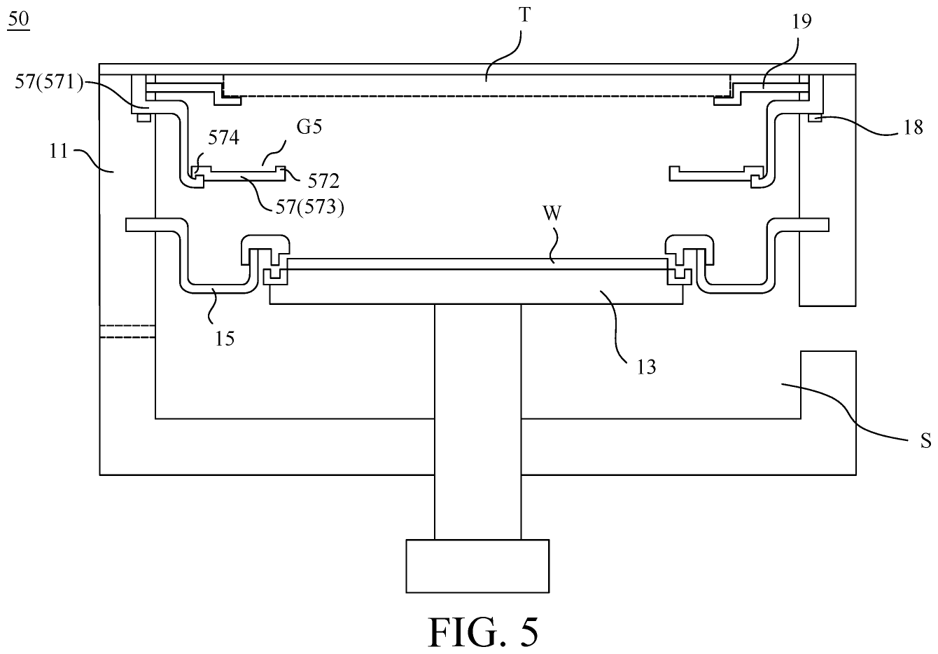

Referring to FIG. 5, which is a schematic diagram of thin-film deposition equipment 50 according to another embodiment of the present disclosure. The embodiment of thin-film deposition equipment 50 is mostly the same as the previous embodiments. In an embodiment, the shielding portion 573 of the shielding component 57 of the thin-film deposition equipment 50 further includes a first protruding portion 572 and a second protruding portion 574, to form a groove (G5) on the shielding portion 573 between the first protruding portion 572 and the second protruding portion 574. The groove (G5) is used to receive a part of the target atoms and to prevent the target atoms deposited on the shielding component 57 from being heated and melting then dripping onto the substrate (W). The first protruding portion 572 may be positioned at an end of the shielding portion 573, and the second protruding portion 574 may be positioned at another end of the shielding portion 573, however the present disclosure is not limited thereto, the first protruding portion 572 and the second protruding portion 574 can be positioned anywhere on the shielding portion 573.

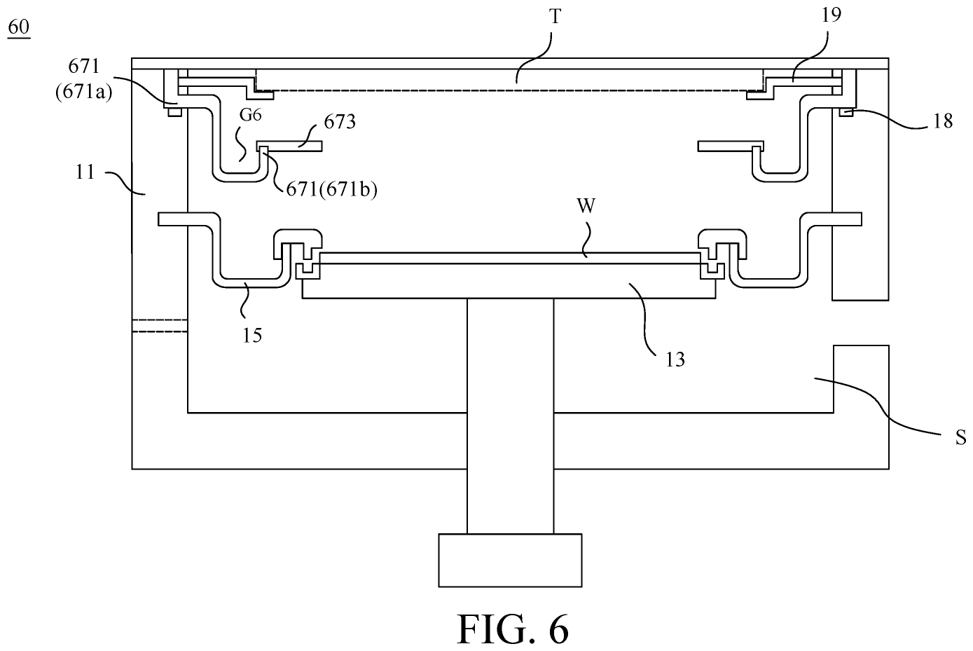

Referring to FIG. 6, which is a schematic diagram of thin-film deposition equipment 60 according to another embodiment of the present disclosure. The embodiment of the thin-film deposition equipment 60 is mostly the same as the previous embodiments. In one embodiment, the connecting portion 671 of the thin-film deposition equipment 60 further includes a seat portion 671a and a holding portion 671b wherein, the seat portion 671a is connected to the chamber 11, and the holding portion 671b is connected to the shielding portion 673. The connecting portion 671 further includes a cavity (G6) disposed between the seat portion 671a and the holding portion 671b, wherein the cavity (G6) is used to receive a part of the target atoms and to prevent the target atoms deposited on the shielding component 37 from being heated and melting and then dripping onto the substrate (W).

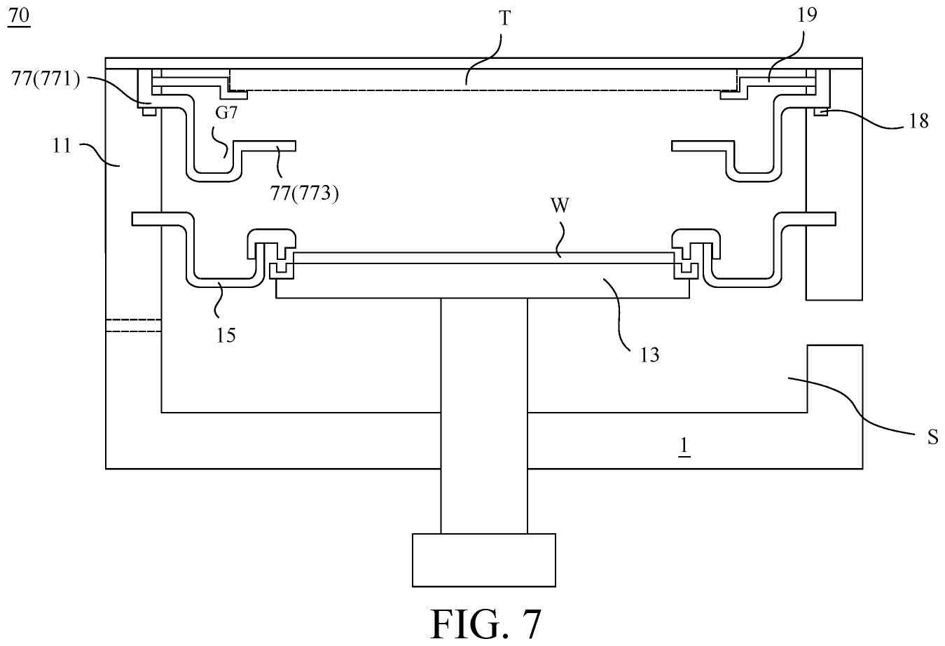

Likewise, the connecting portion 671 and the shielding portion 673 may be two components that are assembled to the shielding component 67. Otherwise as shown in FIG. 7, the connecting portion 771 and the shielding portion 773 of the thin-film deposition equipment 70 may also be formed integrally as one shielding component 77, and has the cavity (G7) formed between the connecting portion 771 and the shielding portion 773, to receive a part of the target atoms and to prevent the target atoms deposited on the shielding component 77 from being heated and melting and then dripping onto the substrate (W).

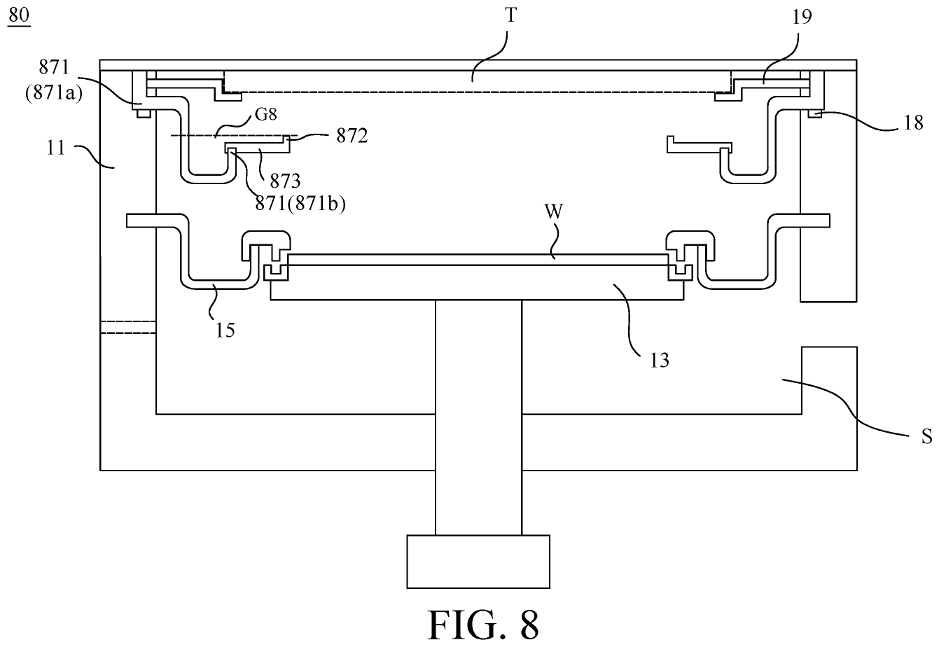

Referring to FIG. 8, which is a schematic diagram of thin-film deposition equipment 80 according to another embodiment of the present disclosure. The embodiment of the thin-film deposition equipment 80 is mostly the same as the previous embodiments. In one embodiment, the connecting portion 871 of the shielding component 87 of the thin-film deposition equipment 80 further includes a seat portion 871a and a holding portion 871b, wherein, the seat portion 871a is connected to the chamber 11, and the holding portion 871b is connected to the shielding portion 873. Furthermore, the shielding portion 873 further includes a first protruding portion 872 to form a cavity (G8) between the first protruding portion 872 and the seat portion 871a. Specifically, the cavity (G8) is formed cooperatively by the shielding portion 873 and the connecting portion 871 of the shielding component 87, for receiving a part of the target atoms and preventing that the target atoms deposited on the shielding component 87 from being heated and melting and then dripping onto the substrate (W). The first protruding portion 872 may be positioned at an end of the shielding portion 873, however the present disclosure is not limited thereto, the first protruding portion 872 can be positioned anywhere on the shielding portion 873.

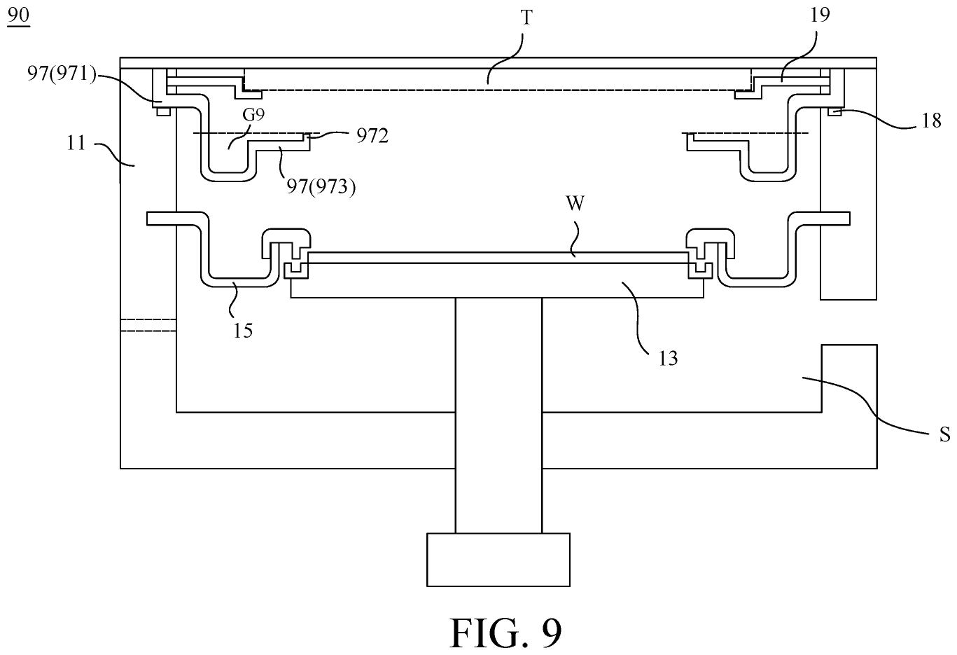

Likewise, the connecting portion 871 and the shielding portion 873 may be two components that are assembled into the shielding component 87. Otherwise as shown in FIG. 9, the connecting portion 971 and the first protruding portion 972 of the shielding portion 973 of the thin-film deposition equipment 90 may also be formed integrally as one shielding component 97, and has the cavity (G9) formed between the first protruding portion 972 and the connecting portion 971 of the shielding portion 973, to receive a part of the target atoms and to prevent the target atoms deposited on the shielding component 97 from being heated and melting and then dripping onto the substrate (W).

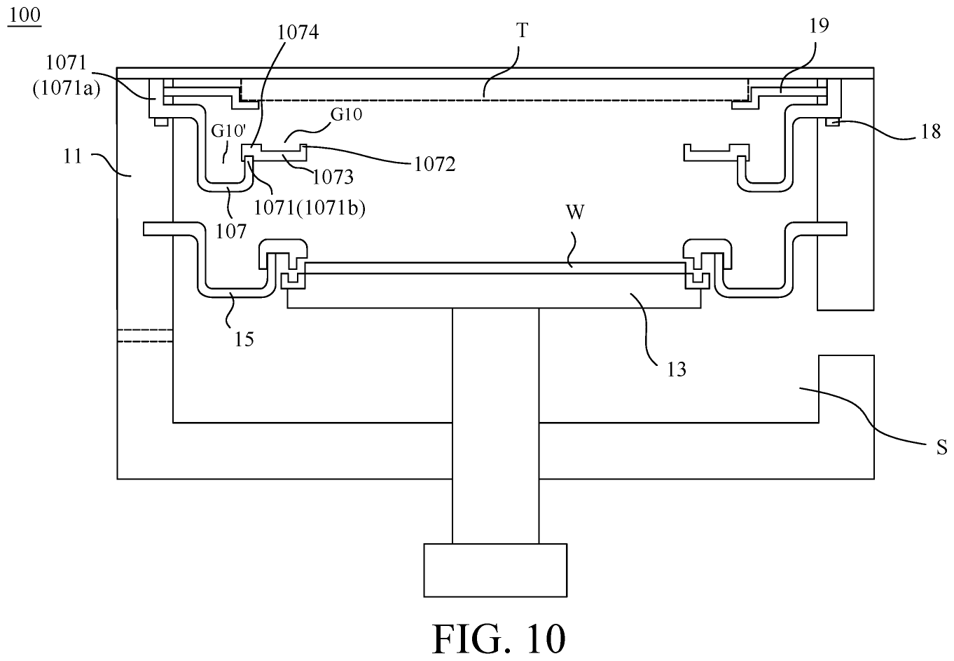

Referring to FIG. 10, which is a schematic diagram of thin-film deposition equipment 100 according to another embodiment of the present disclosure. The embodiment of the thin-film deposition equipment 100 is mostly the same as the previous embodiments. In one embodiment, the connecting portion 1071 of the shielding component 107 of the thin-film deposition equipment 100 further includes a seat portion 1071a and a holding portion 1071b and a cavity (G10′). The seat portion 1071a is connected to the chamber 11, the holding portion 1071b is connected to the shielding portion 1073, and the cavity (G10′) is disposed between the seat portion 671a and the holding portion 671b. Furthermore, the shielding portion 1073 includes a first protruding portion 1072 and a second protruding portion 1074 to form a groove (G10) between the first protruding portion 1072 and the second protruding portion 1074. The cavity (G10′) and the groove (G10) are used to receive a part of the target atoms and to prevent the target atoms deposited on the shielding component 107 from being heated and melting and then dripping onto the substrate (W). The first protruding portion 1072 may be positioned at an end of the shielding portion 1073, and the second protruding portion 1074 may be positioned at another end of the shielding portion 1073, however the present disclosure is not limited thereto, the first protruding portion 1072 and the second protruding portion 1074 can be positioned anywhere on the shielding portion 1073.

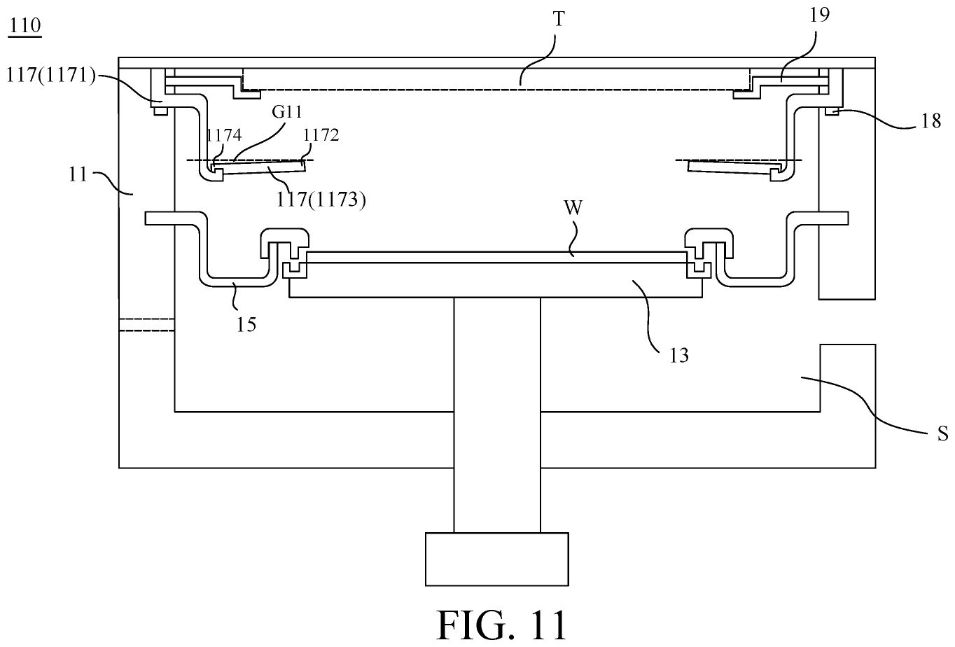

Referring to FIG. 11, which is a schematic diagram of thin-film deposition equipment 110 according to another embodiment of the present disclosure. The embodiment of the thin-film deposition equipment 110 is mostly the same as the previous embodiments. In one embodiment, the shielding component 117 of the thin-film deposition equipment 110 further includes a first end 1174, a second end 1172 and a catch area 1173. The first end 1174 is connected to the connecting portion 1171, the second end 1172 and the first end 1174 face each other, and the catch area 1173 is disposed between the first end 1174 and the second end 1172. A top portion of the second end 1172 is positioned higher than the catch area 1173, to form a cavity (G11) between the second end 1172 and the connecting portion 1171. The cavity (G11) is used to receive a part of the target atoms and to prevent the target atoms deposited on the shielding component 117 from being heated and melting and then dripping onto the substrate (W).

In the abovementioned embodiments, each of the thin-film deposition equipments 10, 20, 30, 40, 50, 60, 70, 80, 90, 100, 110 may further includes a cooling-cycle passage 12 that contacts the shielding component. Specifically, the cooling-cycle passage 12 can contact the connecting portion of the shielding component for transferring a coolant fluid, to decrease temperature of the shielding component, thereby to hasten the cool down of the target atoms deposited on the shielding component and to form a thin film on the shielding component, in order to prevent the target atoms from melting by the heat accumulation, and further avoid the target atoms dripping onto the substrate (W).

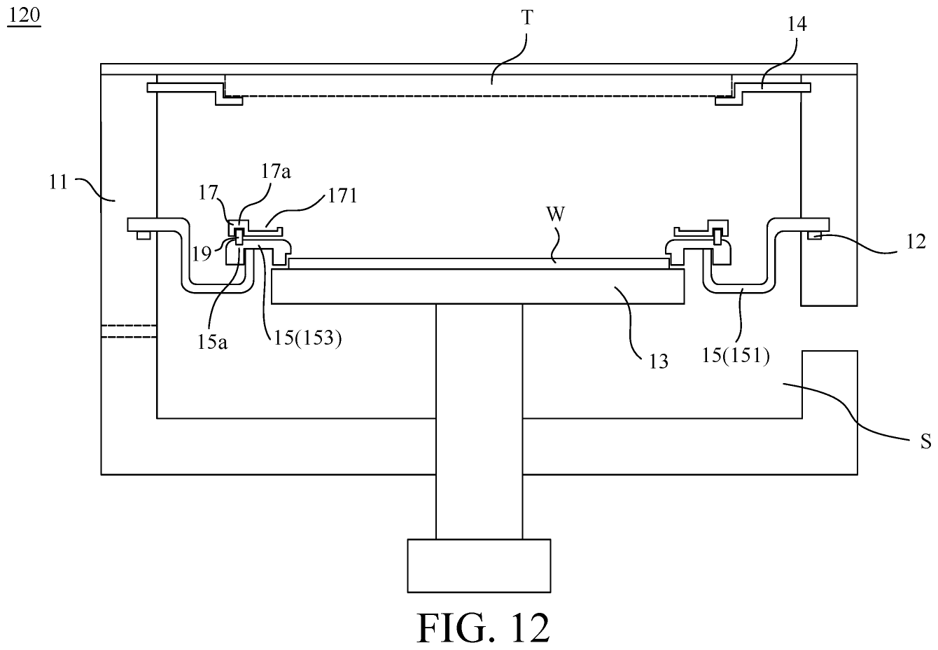

In other embodiments, the shielding component 17 may also be connected to the baffle 15. Referring to FIG. 12, which is a schematic diagram of thin-film deposition equipment 120 according to another embodiment of the present disclosure. As shown in FIG. 12, the thin-film deposition equipment 120 further includes a pin 19 that interconnects the baffle 15 and the shielding component 17. Specifically, the cap ring 153 of the baffle 15 has an upper surface disposed with a first concave portion 15a, the shielding component 17 has a lower surface disposed with a second concave portion 17a, and the pin 19 is engaged with the first concave portion 15a of the baffle 15 and the second concave portion 17a of the shielding component 17, thereby the shielding component 17 is connected to the baffle 15 via the pin 19, wherein the shielding component 17 is positioned higher than the baffle 15.

In other embodiments, other pins 19 with different lengths may be chosen to engage with the first concave portion 15a of the baffle 15 and the second concave portion 17a of the shielding component 17, for adjusting a distance between the shielding component 17 and the baffle 15.

The shielding component 17 is positioned higher than the baffle 15 and shields the baffle 15 to receive a part of the target atoms that are yet deposited on the substrate (W) for the baffle 15. Such that, the shielding component 17 reduces the deposition of target atoms on the baffle 15 and lessen the thin film forming thereon, hence the minimized thin film on the baffle 15 will not flow into an contact area of the baffle 15 and the substrate (W) when being heated 15, and further improves the drawback of slag forming between the baffle 15 and the substrate (W). Likewise, the shielding component 17 may further include a cavity 171 positioned on the upper surface of the shielding component 17. Specifically, the cavity 171 is used to receive a part of the target atoms, and to prevent the target atoms deposited on the shielding component 17 from being heated and melting and then dripping onto the substrate (W). The shielding component 17 may be formed integrally as a single component or an assembly of multiple components, also not limited to align with the baffle 15, the shielding component 17 may be disposed ahead of, behind of or aligned with the baffle 15.

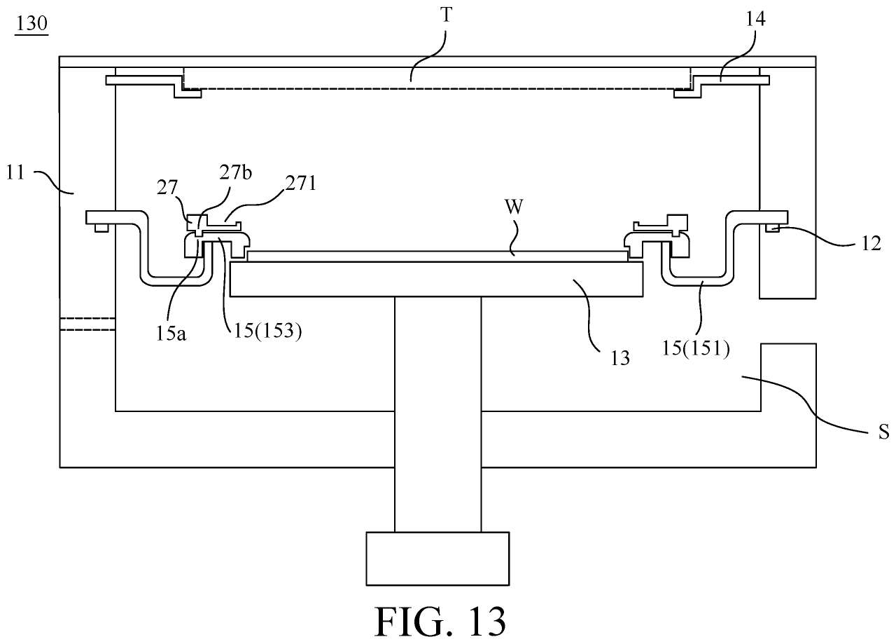

In other embodiments, the thin-film deposition equipment 1 may not include the pin 19. Referring to FIG. 13, which is a schematic diagram of thin-film deposition equipment 130 according to another embodiment of the present disclosure. As shown in FIG. 13, the thin-film deposition equipment 130 has a structure mostly the same as the previous embodiments but different in the shielding component 27, and the baffle 15 and the shielding component 27 are connected with no need of the pin 19.

To be specific, the shielding component 27 has a lower surface disposed with the first protruding portion 27b, and the cap ring 153 of the baffle 15 has an upper surface disposed with a first concave portion 15a. Furthermore, the first concave portion 15a of the baffle 15 is corresponding to and engaged with the first protruding portion 27b of the shielding component 27, thereby the shielding component 27 is connected to the baffle 15 in a position higher than the baffle 15.

The baffle 15 can prevent backside coating of the substrate (W) on the stage 13, the shielding component 27 is positioned higher than and shields the baffle 15 to receive a part of the target atoms that are yet deposited on the substrate (W) for the baffle 15. Such that, the shielding component 27 lessens the thin film formed by the target atoms that are deposited on the baffle 15, hence the minimized thin film on the baffle 15 will not flow from the baffle 15 to an contact area of the baffle 15 and the substrate (W) when being heated 15, thereby to improve the drawback of slag forming between the baffle 15 and the substrate (W). The shielding component 27 may further include the cavity 271 positioned on the upper surface thereof. The cavity 271 is used to receive a part of the target atoms, and to prevent the target atoms deposited on the shielding component 17 from being heated and melting and then dripping onto the substrate (W). The shielding component 27 may be formed integrally as a single component or an assembly of multiple components, also not limited to align with the baffle 15, the shielding component 27 may be disposed ahead of, behind of or aligned with the baffle 15.

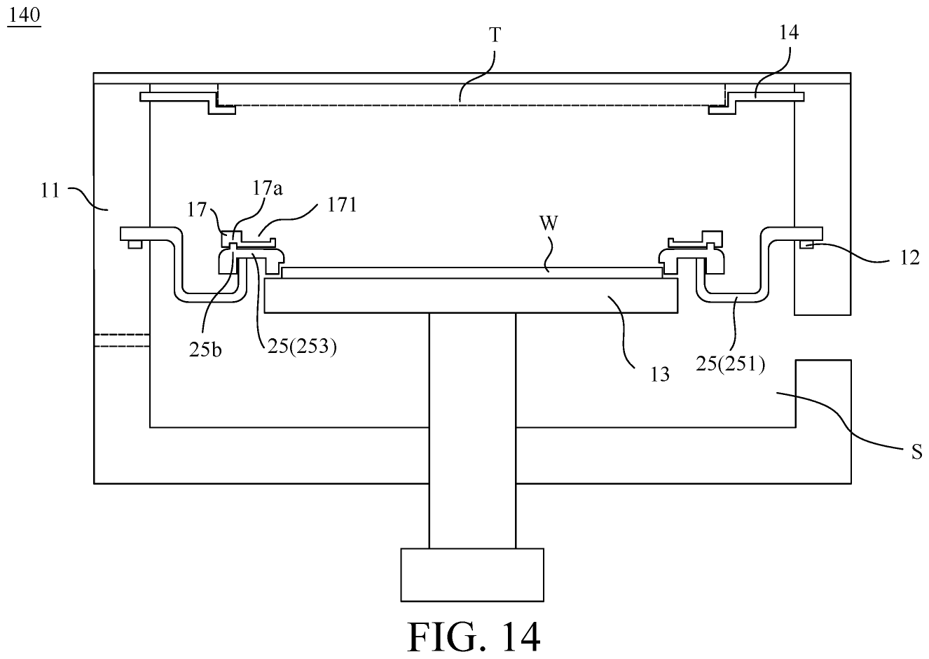

Referring to FIG. 14, which is a schematic diagram of thin-film deposition equipment 140 according to another embodiment of the present disclosure. As shown in FIG. 14, the thin-film deposition equipment 140 has a structure mostly the same as the previous embodiments but different in the baffle 25, and the baffle 25 and the shielding component 17 are connected with no need of the pin 19.

To be specific, the shielding component 17 has a lower surface disposed with a second concave portion 17a, and the cap ring 253 of the baffle 25 has an upper surface disposed with a second protruding portion 25b. Furthermore, the second protruding portion 25b of the baffle 25 is corresponding to and engaged with the second concave portion 17a of the shielding component 17, thereby the shielding component 17 is connected to the baffle 25 and positioned higher than the baffle 25.

The baffle 25 can prevent backside coating of the substrate (W) on the stage 13, the shielding component 17 is positioned higher than the baffle 25 and shields the baffle 25 to receive a part of the target atoms that are yet deposited on the substrate (W) for the baffle 25. Such that, the shielding component 17 lessens the thin film forming on the baffle 25 by the deposition of target atoms, hence the minimized thin film on the baffle 25 will not flow from the baffle 25 to an contact area of the baffle 25 and the substrate (W) when being heated, and thereby to improve the drawback of slag forming between the baffle 25 and the substrate (W). The shielding component 17 may further include a cavity 171 positioned on the upper surface of the shielding component 17. The cavity 171 is used to receive a part of the target atoms, and to prevent that the target atoms deposited on the shielding component 17 from being heated and melting and then dripping onto the substrate (W). Also, the shielding component 17 may be formed integrally as a single component or an assembly of multiple components, also not limited to align with the baffle 25, the shielding component 17 may be disposed ahead of, behind of or aligned with the baffle 25. Moreover, the structure of the baffle 25 can be changed to anyone from the previous embodiments.

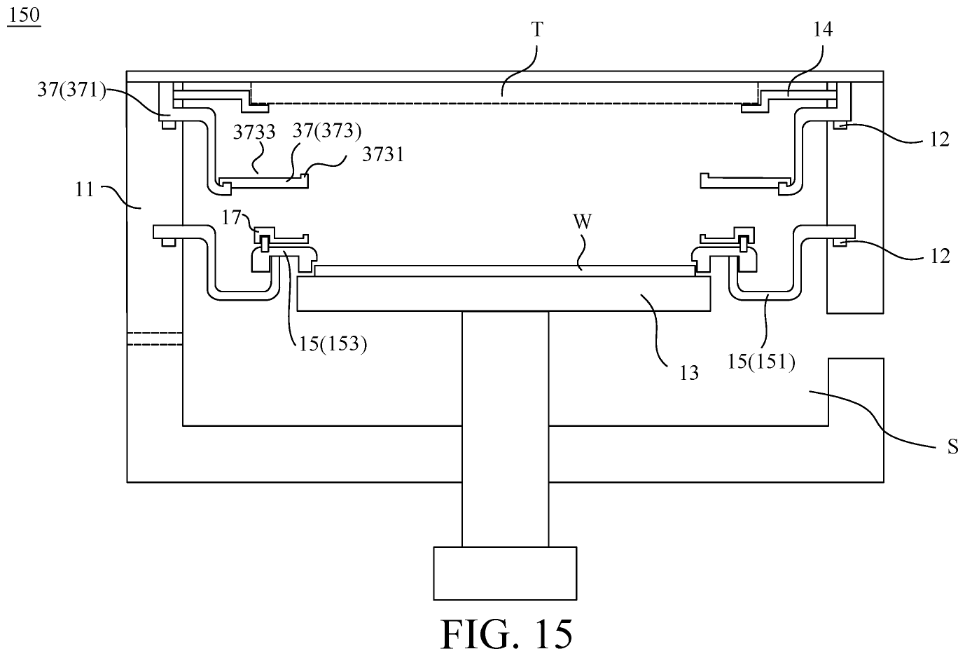

In other embodiments, the thin-film deposition equipment may include two shielding components. Referring to FIG. 15, which is a schematic diagram of thin-film deposition equipment 150 according to another embodiment of the present disclosure. As shown in FIG. 15, the thin-film deposition equipment 150 has a structure mostly the same as the previous embodiments but different in that the thin-film deposition equipment 150 further has an upper shielding component 37. It should be noted, although the baffle 15 and the shielding component 17 of the thin-film deposition equipment 150 are the same as the embodiment shown in FIG. 12, but the baffle 15 and the shielding component 17 may be configured as shown in FIG. 13 and FIG. 14, which have no pin 19 but engage the baffle 15 with the shielding component 17 by protrusion of cavity.

The upper shielding component 37 is connected to the chamber 11 and positioned higher than the shielding component 17. Specifically, the upper shielding component 37 has a second connecting portion 371 and a second shielding portion 373, wherein the second shielding portion 371 is connected to the chamber 11 via the second connecting portion 371. As shown in FIG. 12, the second connecting portion 371 and the second shielding portion 373 may be two or more member parts assembled into the upper shielding component 37, otherwise, the second connecting portion 371 and the second shielding portion 373 may be formed integrally as one upper shielding component 37.

In one embodiment, the upper shielding component 37 further includes a protruding portion 3731 on the second shielding portion 373, to form an upper shielding-component cavity 3733 between the protruding portion 3731 and the chamber 11. To be specific, the upper shielding-component cavity 3733 is positioned between the protruding portion 3731 and the second connecting portion 371. The upper shielding-component cavity 3733 is also used to receive a part of the target atoms and to reduce deposition of the target atoms on the shielding component 17 and the baffle 15, as so to enhance the prevention of the target atoms deposited on the shielding component 17 from being heated and melting and then dripping onto the substrate (W). The protruding portion 3731 may be positioned at an end of the upper shielding component 37, such as at the end of the second shielding portion 373, however the present disclosure is not limited thereto, the protruding portion 3731 may be disposed anywhere on the second shielding portion 373. The upper shielding component 37 may be made of stainless steel, titanium or aluminum alloy, for example.

In abovementioned embodiments, each of the thin-film deposition equipments 120, 130, 140, 150 may further include a cooling-cycle passage 12, wherein the cooling-cycle passage 12 contacts the main bodies 151, 251 of the baffles 15, 25. The cooling-cycle passage 12 is used to transfer the coolant fluid, to decrease temperature of the baffles 15-25 and the shielding components 17, 27, thereby to hasten the cool down of the target atoms deposited on the shielding components 17, 27 and to form a thin film on the shielding components 17, 27, to prevent the melting of the target atoms due to the heat accumulation, and to further avoid the target atoms dripping onto the substrate (W). Furthermore, the cooling-cycle passage 12 may also contact the upper shielding component 37. To be specific, the cooling-cycle passage 12 can contact the upper shielding component 37, such as to contact the second connecting portion 371 and decrease temperature of the upper shielding component 37, in order to hasten the cool down of the target atoms deposited on the upper shielding component 37.

In summary of abovementioned embodiments, compare to the conventional technology, the thin-film deposition equipment according to the present disclosure can provide the following technical advantage.

In the conventional technology, the baffle for locking the substrate suffers from the deposition of target atoms and the forming of thin film, so when the heat accumulates more and more during the process, the thin film on the baffle will melt and flows to the substrate or the contact area between the baffle and the substrate, cause nasty mess of the substrate or cause the substrate and the baffle stick with each other, then further worsen the yield of product and the reliability. As to the thin-film deposition equipment according to the present disclosure, which shields the baffle by the shielding component, to prevent excessive deposition of target atoms on the baffle, therefore as the thin film on the baffle being minimized, this can keep the heated thin film from melting and flowing to contaminate the substrate, thereby to improve the quality of the product.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. A thin-film deposition equipment, comprising:
a chamber having a containing space;
a stage positioned within the containing space for carrying at least one substrate;
at least one baffle positioned within the containing space for preventing the substrate on the stage from backside coating; and
at least one shielding component is positioned higher the baffle, wherein the shielding component has an upper surface disposed with a cavity.

2. The thin-film deposition equipment as claimed in claim 1, further comprising a pin that is engaged with a first concave portion on an upper surface of the baffle and a second concave portion on a lower surface of the shielding component, thereby the shielding component is connected to the baffle via the pin.

3. The thin-film deposition equipment as claimed in claim 2, wherein a distance between the shielding component and the baffle can be adjusted by replacing the pin for another pin with different length.

4. The thin-film deposition equipment as claimed in claim 2, further comprising at least one cooling-cycle passage that contacts the baffle, for transferring a coolant fluid to decrease temperature of the baffle.

5. The thin-film deposition equipment as claimed in claim 1, wherein:
the baffle has an upper surface disposed with a first concave portion;
the shielding component has a lower surface disposed with a first protruding portion; and
the first concave portion of the baffle is corresponding to and engaged with the first protruding portion of the shielding component, such that the shielding component is connected to the baffle.

6. The thin-film deposition equipment as claimed in claim 1, wherein:
the baffle has an upper surface disposed with a second protruding portion;
the shielding component has a lower surface disposed with a second concave portion; and
the second protruding portion of the baffle is corresponding to and engaged with the second concave portion of the shielding component, such that the shielding component is connected to the baffle.

7. The thin-film deposition equipment as claimed in claim 6 further comprising at least one cooling-cycle passage that contacts the baffle, for transferring a coolant fluid to decrease temperature of the baffle.

8. The thin-film deposition equipment as claimed in claim 1 further comprising an upper shielding component that is connected to the chamber and that is positioned higher than the shielding component.

9. The thin-film deposition equipment as claimed in claim 8, wherein the upper shielding component has an end disposed with a protruding portion to form an upper shielding-component cavity between the protruding portion and the chamber.

10. The thin-film deposition equipment as claimed in claim 8, wherein the upper shielding-component is made of stainless, titanium or aluminum alloy.

11. The thin-film deposition equipment as claimed in claim 8, further comprising at least one cooling-cycle passage that contacts the upper shielding component, for transferring a coolant fluid to decrease temperature of the upper shielding component.

12. The thin-film deposition equipment as claimed in claim 1, wherein:
the shielding component has a connecting portion and a shielding portion; and
the shielding portion is connected to the chamber via the connecting portion, and further comprises a first protruding portion, thereby the cavity is formed between the first protruding portion and the connecting portion.

13. The thin-film deposition equipment as claimed in claim 12, wherein the shielding portion further comprises a second protruding portion to form a groove disposed between the first protruding portion and the second protruding portion.

14. The thin-film deposition equipment as claimed in claim 12, wherein:
the connecting portion further comprises a seat portion and a holding portion;
the seat portion is connected to the chamber;
the holding portion is connected to the shielding portion; and
the connecting portion further comprises a cavity between the seat portion and the holding portion.

15. The thin-film deposition equipment as claimed in claim 14, wherein the shielding component further comprises a second protruding portion, to form a groove on the shielding portion between the first protruding portion and the second protruding portion.

16. The thin-film deposition equipment as claimed in claim 12, wherein:
the shielding portion further comprises a first end, a second end and a catch area;
the first end is connected to the connecting portion;
the second end and the first end face each other;
the catch area is disposed between the first end and the second end; and
the second end has a top portion that is positioned higher the catch area, thereby the cavity is disposed between the second end and the connecting portion.

17. The thin-film deposition equipment as claimed in claim 12, further comprising at least one cooling-cycle passage that contacts the shielding component, for transferring a coolant fluid to decrease temperature of the shielding component.

18. The thin-film deposition equipment as claimed in claim 1, wherein the shielding-component is made of stainless steel, titanium or aluminum alloy.

19. The thin-film deposition equipment as claimed in claim 1, further comprising a coolant-gas inlet that contacts the stage, to transfer a coolant gas between the stage and the substrate, and to decrease temperature of the substrate.

20. The thin-film deposition equipment as claimed in claim 1, further comprising a target shield that is positioned above the shielding component.
